(19) United States
(12) Patent Application Publication
(10) Pub. No.: US 2026/0331950 A1
(43) Pub. Date: Oct. 22, 2026

(54) WIRELESS CHARGING STAND

(71) Applicant: Ying Lu, Shenzhen (CN)

(72) Inventor: Ying Lu, Shenzhen (CN)

(21) Appl. No.: 19/185,412

(22) Filed: Apr. 22, 2025

(51) Int. Cl. H02J 50/00; H02J 50/10; H02J 50/40; H02J 50/90; H05K 5/00; H05K 5/02

(52) U.S. Cl. CPC H02J 50/005; H02J 50/10; H02J 50/402; H02J 50/90; H05K 5/0086; H05K 5/0226; H05K 5/0247

(57) ABSTRACT

A wireless charging stand, including a first wireless charging module and a second wireless charging module. The first wireless charging module includes a first housing and a first wireless charging assembly arranged within the first housing; the first housing includes a first panel surface and a rotating portion disposed on the first panel surface. The second wireless charging module includes a second housing and a second wireless charging assembly arranged within the second housing; the second housing includes a second panel surface opposite and adjacent to the first surface, and the second panel surface is arranged with a mating portion; the rotating portion is rotatably connected to the mating portion around a first axis. A power supply component is arranged in the first housing or the second housing and is electrically connected to the first wireless charging assembly and the second wireless charging assembly.

### TECHNICAL FIELD

The present disclosure relates to the technical field of auxiliary equipment for electronic devices, and more specifically to a wireless charging stand.

### BACKGROUND

With the proliferation of electronic devices and the escalating demand for user convenience and spatial tidiness in daily life, wireless charging stands have emerged as an innovative solution. Leveraging wireless charging technology, the wireless charging stands may eliminate cable dependency and enhance user experience through simplified operation. To meet the demand for multi-device charging, mainstream wireless charging stands on the current market predominantly integrate at least two wireless charging modules. This design enables simultaneous power delivery to commonly used devices such as smartphones, smartwatches, and Bluetooth earphones on a single stand, obviating the need for multiple sockets or portable chargers. Consequently, the charging process is substantially streamlined, significantly improving lifestyle convenience.

To achieve portability and compact storage, many wireless charging stands are adopted with a longitudinal folding design. This design allows users to collapse the stand into a compact form when idle, substantially reducing its spatial footprint for effortless storage and transportation. However, while this foldable architecture enhances practicality, it introduces non-negligible technical and aesthetic challenges. Firstly, the partially-exposed rotating shaft of the folded stand may create gaps prone to debris accumulation, such as paper fibers, hair entanglement, or lint ingress. Once the foreign particles penetrate these gaps, they may impede rotational mechanics, leading to mechanical failure or operational obstruction. Secondly, the exposed rotating shaft and gaps may disrupt the stand's aesthetic uniformity, diminishing its visual appeal and market desirability.

The above content is provided solely for the purpose of assisting in understanding the technical solutions described in the present disclosure and does not constitute acknowledgment that the above content constitutes prior art.

### SUMMARY OF THE DISCLOSURE

A wireless charging stand includes a first wireless charging module and a second wireless charging module; wherein the first wireless charging module includes a first housing and a first wireless charging assembly arranged within the first housing; the first housing includes a first panel surface and a rotating portion disposed on the first panel surface; the second wireless charging module includes a second housing and a second wireless charging assembly arranged within the second housing; the second housing includes a second panel surface opposite and adjacent to the first surface, and the second panel surface is arranged with a mating portion; the rotating portion is rotatably connected to the mating portion around a first axis, enabling the second wireless charging module to rotate relative to the first wireless charging module along the first panel surface; the first axis is perpendicular to the first panel surface and the second panel surface; a power supply component is arranged in the first housing or the second housing and is electrically connected to the first wireless charging assembly and the second wireless charging assembly.

### BRIEF DESCRIPTION OF THE DRAWINGS

To illustrate the technical solutions of the embodiments of the present disclosure more clearly, the accompanying drawings of the embodiments will be briefly described below, and it will be apparent that the accompanying drawings in the following description relate only to some embodiments of the present disclosure and other drawings may be obtained from these drawings by those skilled in the art without creative labor.

FIG. 1 is a structural schematic view of a wireless charging stand according to some embodiments of the present disclosure, where a second wireless charging module is in a stacked position relative to a first wireless charging module.

FIG. 2 is a rear view of the wireless charging stand shown in FIG. 1.

FIG. 3 is a right view of the wireless charging stand shown in FIG. 1.

FIG. 4 is a front view of the wireless charging stand shown in FIG. 1.

FIG. 5 is a structural schematic view of a wireless charging stand according to other embodiments of the present disclosure, where a second wireless charging module is in a misaligned position relative to a first wireless charging module.

FIG. 6 is a rear view of the wireless charging stand shown in FIG. 5.

FIG. 7 is a cross-sectional view of the wireless charging stand shown in FIG. 5, where a support structure is in an open state.

FIG. 8 is an enlarged view of an area A circumscribed in FIG. 7.

FIG. 9 is a structural schematic view of a first wireless charging module of a wireless charging stand according to some embodiments of the present disclosure.

FIG. 10 is an exploded view of the first wireless charging module shown in FIG. 9.

FIG. 11 is a structural schematic view of the first wireless charging module shown in FIG. 9 after a first panel is removed.

FIG. 12 is a structural schematic view of an enclosure frame and a rotating portion shown in FIG. 10.

FIG. 13 is a partial enlarged view of an area B circumscribed in FIG. 12.

FIG. 14 is a structural schematic view of a second wireless charging module of a wireless charging stand according to some embodiments of the present disclosure.

FIG. 15 is an exploded view of the second wireless charging module shown in FIG. 14.

FIG. 16 is a structural schematic view of the second wireless charging module shown in FIG. 15 from another viewing angle.

FIG. 17 is a structural schematic view of an insulating inner housing shown in FIG. 15.

FIG. 18 is a structural schematic view of a wireless charging stand according to some embodiments of the present disclosure, after a second panel, a control board, and a coil mounting frame of a second wireless charging module, and a limiting disk of a first wireless charging module are removed.

FIG. 19 is a partial enlarged view of an area C circumscribed in FIG. 18.

FIG. 20 is a structural schematic view of a light guide member of a wireless charging stand according to some embodiments of the present disclosure.

FIG. 21 is a structural schematic view of the light guide member shown in FIG. 20 from another viewing angle.

### REFERENCE NUMERALS

| No. | Name | No. | Name | No. | Name |
|---|---|---|---|---|---|
| 100 | First wireless | 110 | First housing | 111 | First panel surface |
| | charging module | | | | |
| 112 | Annular protrusion | 113 | Rotating portion | 114 | Rotating cylinder |
| 115 | Limiting disk | 116 | Installation disk | 117 | Positioning slot |
| 118 | Limiting slot | 119 | First side wall | 120 | First main housing |
| 121 | First opening | 122 | First panel | 130 | First wireless |
| | | | | | charging assembly |
| 131 | First coil | 140 | Power supply | 150 | First magnetic |
| | | | component | | member |
| 160 | Enclosure frame | 170 | Connection plate | 180 | Wire clamping |
| | | | | | plate |
| 190 | Damping ring | 200 | Second wireless | 210 | Second housing |
| | | | charging module | | |
| 211 | Second panel | 212 | Rotating through | 213 | Embedding groove |
| | surface | | hole | | |
| 214 | Through hole | 215 | Light-transmitting | 220 | Mating portion |
| | | | hole | | |
| 221 | Embedded | 222 | Positioning tab | 223 | Protruding portion |
| | protruding ring | | | | |
| 224 | Guide post | 225 | Limiting insertion | 226 | Spring |
| | | | block | | |
| 227 | Second side wall | 230 | Second main | 231 | Second opening |
| | | | housing | | |
| 232 | Second panel | 240 | Second wireless | 241 | Second coil |
| | | | charging assembly | | |
| 242 | Control board | 250 | Second magnetic | 260 | Support structure |
| | | | member | | |
| 261 | Support member | 262 | Fixing member | 263 | Hinge member |
| 280 | Insulating inner | 281 | Device placement | 290 | Charging Interface |
| | housing | | portion | | |
| 291 | Light guide member | 292 | Light guide ring | 293 | Installation Slot |
| 294 | Light guide cylinder | 295 | LED | 296 | Decorative sheet |
| | | | accommodation | | |
| | | | slot | | |

The realization of the purpose, functional features, and advantages of the present disclosure will be further described in conjunction with the embodiments and with reference to the accompanying drawings.

### DETAILED DESCRIPTION

The technical solutions in the embodiments of the present disclosure will be described clearly and completely in the following in conjunction with the accompanying drawings in the embodiments of the present disclosure, and it is obvious that the described embodiments are only a part of the embodiments of the present disclosure and not all of the embodiments. Based on the embodiments in the present disclosure, all other embodiments obtained by those skilled in the art without creative labor fall within the scope of the present disclosure. In addition, the technical solutions between various embodiments can be combined with each other, but it must be based on the fact that those skilled in the art is able to realize it. When the combination of the technical solutions appears to be contradictory or unattainable, it should be considered that the combination of such technical solutions does not exist, and is not included in the scope claimed by the present disclosure.

It should be noted that when the embodiments of the present disclosure involve directional indications (such as up, down, left, right, forward, back . . . ), the directional indications are only intended to explain a relative positional relationship, a movement, etc. between the various components in a particular attitude. When the particular attitude changes, the directional indications are also changed accordingly.

In the embodiments of the present disclosure, unless otherwise explicitly specified and limited, a first feature being “on” or “under” a second feature may refer to direct contact between the first and second features, or indirect contact between the first and second features through an intermediate medium. Furthermore, the first feature being “above”, “on top of”, or “on” the second feature may refer to the first feature being directly above or diagonally above the second feature, or may simply indicate that the horizontal height of the first feature is greater than that of the second feature. The first feature being “below”, “under”, or “on the bottom of” the second feature may refer to the first feature being directly below or diagonally below the second feature, or may simply indicate that the horizontal height of the first feature is less than that of the second feature.

In the embodiments of the present disclosure, unless otherwise explicitly specified and limited, terms such as “installed”, “coupled”, “connected”, and “fixed” should be interpreted broadly, for example, they may refer to fixed connections or removable connections, or integrated formation; they may be mechanical connections, electrical connections, or connections that allow communication between components; they may be direct connections or indirect connections via an intermediate medium; they may represent internal communication between two components or an interactive relationship between two components, unless otherwise explicitly limited. For those skilled in the art, the specific meaning of the above terms in the present disclosure may be understood based on the specific context.

In addition, when the embodiments of the present disclosure contain descriptions involving “first”, “second”, etc., the descriptions of “first”, “second”, etc. are intended only for descriptive purposes, and are not to be construed as indicating or implying their relative importance or implicitly specifying the number of the indicated technical features. That is, a feature defined as “first” or “second” may include at least one such feature either explicitly or implicitly. In addition, the meaning of “and/or” in the whole text is to include three concurrent solutions. For example, “A and/or B” includes an A solution, a B solution, and a solution in which A and B are satisfied at the same time.

The present disclosure proposes a wireless charging stand for wirelessly charging electronic devices such as mobile phones, electronic watches, and Bluetooth earphones.

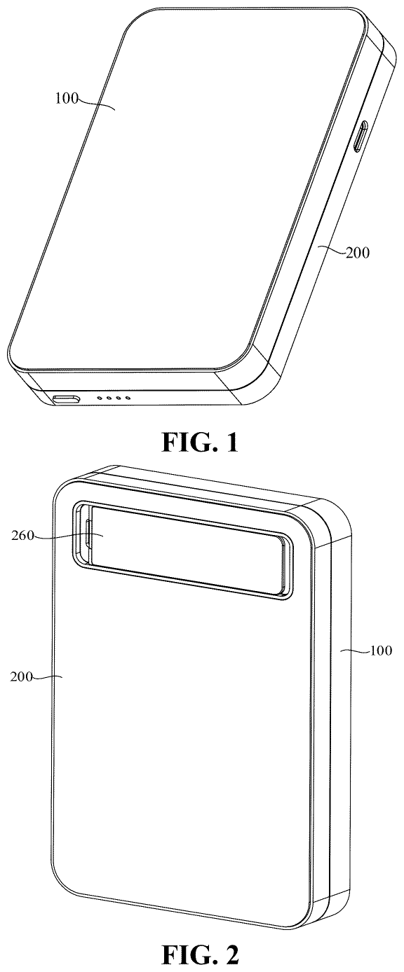

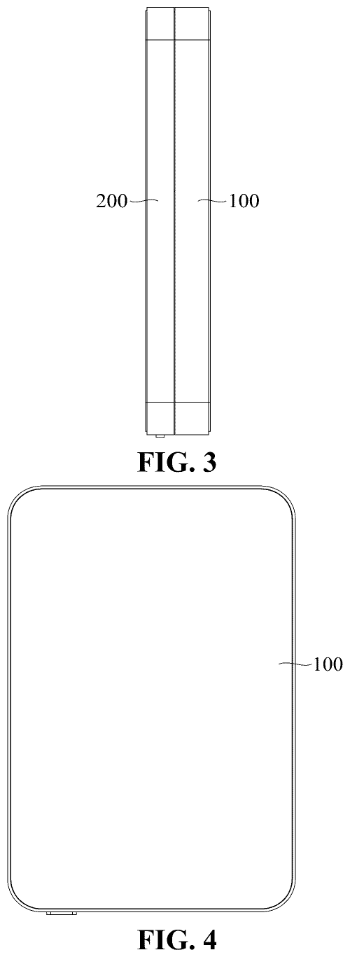

In the embodiments of the present disclosure, referring to FIGS. 1 to 11, the wireless charging stand includes a first wireless charging module 100 and a second wireless charging module 200.

The first wireless charging module 100 includes a first housing 110 and a first wireless charging assembly 130 arranged within the first housing 110; the first housing 110 includes a first panel surface 111 and a rotating portion 113 disposed on the first panel surface 111.

The second wireless charging module 200 includes a second housing 210 and a second wireless charging assembly 240 arranged within the second housing 210; the second housing 210 includes a second panel surface 211 opposite and adjacent to the first surface 111, and the second panel surface 211 is arranged with a mating portion 220; the rotating portion 113 is rotatably connected to the mating portion 220 around a first axis, enabling the second wireless charging module 200 to rotate relative to the first wireless charging module 100 along the first panel surface 111; the first axis is perpendicular to the first panel surface 111 and the second panel surface 211.

A power supply component 140 is arranged in the first housing 110 or the second housing 210 and is electrically connected to the first wireless charging assembly 130 and the second wireless charging assembly 240.

The wireless charging module refers to a module that transmits electrical energy to electronic devices via a wireless electrical connection. Typically, the wireless charging module includes a transmitter coil, while the electronic device has a receiver coil. When the receiver coil of the electronic device aligns with the transmitter coil of the wireless charging module, the wireless charging module supplies power to the electronic device wirelessly via electromagnetic induction or magnetic resonance principles.

In the present disclosure, the first wireless charging assembly 130 and the second wireless charging assembly 240 both have transmitter coils, which are each typically wound with copper wire (Litz Wire) into a circular or square shape. The transmitter coils of the first wireless charging assembly 130 and the second wireless charging assembly 240 may be designed to correspond to electronic devices to be charged. For example, the transmitter coils of the first wireless charging assembly 130 and the second wireless charging assembly 240 may both be designed to charge a smartphone; or, the transmitter coil of the first wireless charging assembly 130 may be designed to charge a smartphone, and the transmitter coil of the second wireless charging assembly 240 may be designed to charge electronic devices such as a watch or Bluetooth headphones. The specific dimensions and design of the transmitter coils of the first wireless charging assembly 130 and the second wireless charging assembly 240 are not further specified herein. The electronic devices may be placed directly on the first wireless charging module 100 and the second wireless charging module 200 for charging. Alternatively, magnets may be installed on outer or inner rings of the first wireless charging assembly 130 and the second wireless charging assembly 240 to magnetically attach the electronic devices, enabling the wireless charging stand to securely hold the electronic devices even when placed vertically or at an angle.

The power supply component 140 may be electrically connected to the transmitter coils of the first wireless charging assembly 130 and the second wireless charging assembly 240 via wires. Alternatively, when necessary, the electrical connection may be made using pins and conductive rings. Since the first wireless charging assembly 130 and the second wireless charging assembly 240 are electrically connected to the power supply component 140, the first wireless charging assembly 130 and the second wireless charging assembly 240 may share a single main control board (main control chip), on which drive circuits for the first wireless charging module 100 and the second wireless charging module 200 are arranged. Of course, in some embodiments, the first wireless charging assembly 130 and the second wireless charging assembly 240 may each be configured with a separate main control chip.

The first panel surface 111 and the second panel surface 211 refer to planar surfaces, and the first panel surface 111 being opposite to the second panel surface 211 refers to the first panel surface 111 and the second panel surface 211 being in a parallel or nearly parallel arrangement. The first panel surface 111 being adjacent to the second panel surface 211 refers to the first panel surface 111 and the second panel surface 211 being in a state of close contact, with a very small or virtually non-existent gap therebetween. In some embodiments, the gap between the first panel surface 111 and the second panel surface 211 is less than or equal to 1 mm. By arranging the rotating portion 113 on the first panel surface 111 and the mating portion 220 on the second panel surface 211 that rotates in conjunction with the rotating portion 113 around the first axis, the first wireless charging module 100 and the second wireless charging module 200 are rotatable along the first panel surface 111 (second panel surface 211), such that the first wireless charging module 100 and the second wireless charging module 200 can hide the rotating portion 113 and the mating portion 220 in any rotational state, thereby preventing them from being exposed, which may prevent unsmooth rotation and jamming caused by hair, paper scraps, and other debris getting tangled between the rotating portion 113 and the mating portion 220, and further ensure the smoothness and consistency of the overall appearance of the wireless charging stand, so as to enhance the product's aesthetic appeal.

The materials of the first housing 110 and the second housing 210 may be varied, such as metal, plastic, or glass. The first housing 110 and the second housing 210 may be made of different materials in different parts according to requirements. The materials of the first housing 110 and the second housing 210 are not specifically limited herein. The shapes of the first housing 110 and the second housing 210 may be varied. For example, the first housing 110 and the second housing 210 may be designed as plate-shaped structures. However, in some embodiments, the first housing 110 and the second housing 210 may be configured as hemispherical or other shapes, provided that the first housing 110 includes the first panel surface 111 and the second housing 210 includes the second panel surface 211.

The first axis is perpendicular to the first panel surface 111 and the second panel surface 211, i.e., the first axis is parallel to or collinear with the normal direction of the first panel surface 111 and the second panel surface 211. The structural form of the rotating portion 113 and the mating portion 220 may be diverse. For example, the rotating portion 113 and the mating portion 220 may both be cylindrical structures; or, the rotating portion 113 may define an annular groove, and the mating portion 220 may be arranged with an annular protrusion 112 that matches the annular groove, thereby achieving a rotational connection between the rotating portion 113 and the mating portion 220. The specific structure of the rotating portion 113 and the mating portion 220 is not limited herein, provided that the rotating portion 113 and the mating portion 220 can be rotatably connected around the first axis. It should be noted that the rotating portion 113 is fixedly connected to the first panel surface 111, and the mating portion 220 is fixedly connected to the second panel surface 211. Each of the rotating portion 113 and the mating portion 220 may be integrally formed (in a one-piece structure) or separately formed with its corresponding housing according to actual requirements. The relative rotational angle between the first wireless charging module 100 and the second wireless charging module 200 may be designed according to actual requirements, such as 360 degrees, 180 degrees, or 90 degrees, which is not limited herein.

The power supply component 140 may specifically be a rechargeable battery. The power supply component 140 is first charged by an external power source, and then the power supply component 140 can provide power to the first wireless charging assembly 130 and the second wireless charging assembly 240. By arranging the power supply within the first housing 110 or the second housing 210, the entire wireless charging stand forms a power bank module. That is, the wireless charging stand does not require an external power source and can directly supply power to the first wireless charging assembly 130 and the second wireless charging assembly 240 via the built-in power supply component 140, thereby enabling users to charge electronic devices such as smartphones, Bluetooth earphones, and watches in outdoor settings or environments without external power sources.

The wireless charging stand of the present disclosure is arranged with the power supply component 140 within the first wireless charging module 100 or the second wireless charging module 200. In this way, when not connected to an external power source, the wireless charging stand can directly supply power to the first wireless charging assembly 130 and the second wireless charging assembly 240 via the built-in power supply component 140, thereby enabling users to charge electronic devices such as smartphones, Bluetooth earphones, and watches in outdoor settings or environments without external power sources. Additionally, the first wireless charging module 100 of the wireless charging stand includes the first panel surface 111 and the rotating portion 113 disposed on the first panel surface 111, while the second wireless charging module 200 includes the second panel surface 211 and the mating portion 220 disposed on the second panel surface 211. The rotating portion 113 is rotatably connected to the mating portion 220 around the normal of the first panel surface 111, enabling the second wireless charging module to rotate relative to the first wireless charging module along the first panel surface 111. Thus, the first wireless charging module 100 and the second wireless charging module 200 can hide the rotating portion 113 and the mating portion 220 in any rotational state, preventing them from being exposed, which may prevent unsmooth rotation and jamming caused by hair, paper scraps, and other debris getting tangled between the rotating portion 113 and the mating portion 220, and further ensure the smoothness and consistency of the overall appearance of the wireless charging stand, so as to enhance the product's aesthetic appeal.

In some embodiments, as shown in FIG. 1 to 4, the first housing 110 and the second housing 210 are each plate-shaped, and the first panel surface 111 and the second panel surface 211 have the same shape and area; the second wireless charging module 200 can rotate relative to the first wireless charging module 100 to a stacked position, and at the stacked position, an outer peripheral wall of the first housing 110 is aligned with an outer peripheral wall of the second housing 210.

In the embodiments, the first housing 110 and the second housing 210 are plate-shaped, i.e., the first housing 110 and the second housing 210 are each of a flat structure and have two opposing panel surfaces. The outer contour shapes of the first housing 110 and the second housing 210 may be various, such as circular, elliptical, square, rectangular, etc. To ensure the battery capacity of the wireless charging stand, the outer contour shapes of the first housing 110 and the second housing 210 may be rounded rectangular shapes. The first panel surface 111 and the second panel surface 211 have the same shape and area, and when stacked, the outer peripheral walls of the first housing 110 and the second housing 210 are aligned. In this way, the entire wireless charging stand can be stacked into a large plate-like structure. When the user holds or stores the charging stand, the outer peripheral walls of the first wireless charging module 100 and the second wireless charging module 200 do not protrude outward, thereby improving the user's grip comfort. In addition, since the outer peripheral walls of the first housing 110 and the second housing 210 are aligned, the overall appearance of the wireless charging stand remains smooth and aesthetically pleasing.

Furthermore, as shown in FIGS. 1 and 2, the outer peripheral wall of the first housing 110 extends in a straight line along the thickness of the first housing 110, while the outer peripheral wall of the second housing 210 extends in a straight line along the thickness of the second housing 210.

In the embodiments, the outer peripheral walls of the first housing 110 and the second housing 210 extend in a straight line along the thickness direction of their respective plates. This means that there is no curved transition between the outer peripheral wall of the first housing 110 and its two opposite panel surfaces, and no curved transition between the outer peripheral wall of the second housing 210 and its two opposite panel surfaces, or there is only a curved transition with a very small radius, such as a radius of less than 0.5 mm. In this way, the outer peripheral wall of the first housing 110 and the outer peripheral wall of the second housing 210 can be closely adjacent and nearly attached, thereby minimizing the gap between the outer peripheral walls of the first housing 110 and the second housing 210, which may prevent small debris from becoming trapped in the gap while ensuring the continuity and smoothness of the appearance of the first housing 110 and the second housing 210, so as to improve the overall usability and aesthetic appeal of the wireless charging module.

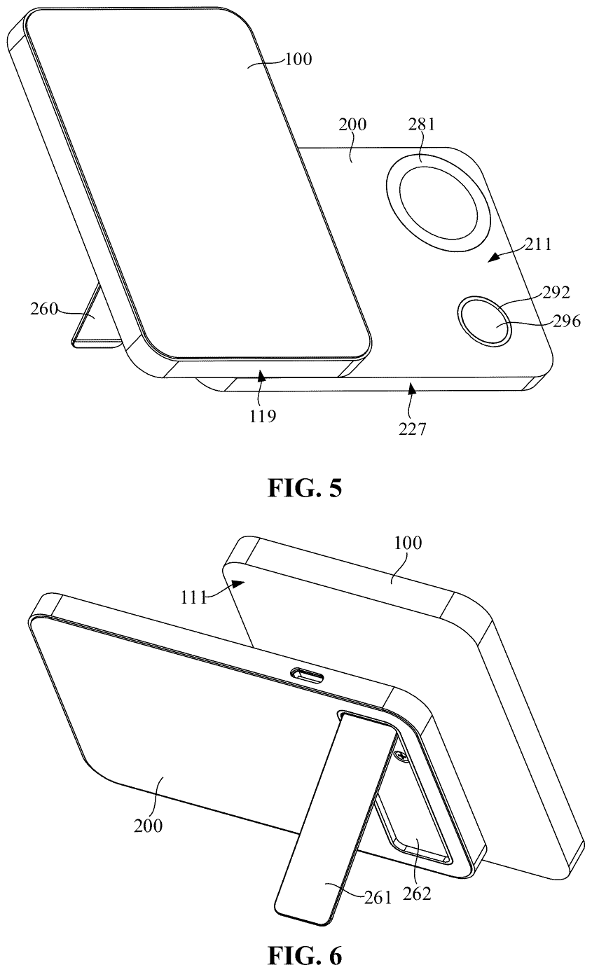

In some embodiments, as shown in FIGS. 5 and 6, the first wireless charging assembly 130 is disposed within the first housing 110 on a side away from the first panel surface 111, the second wireless charging assembly 240 is disposed within the second housing 210 on a side near the second panel surface 211, and the second wireless charging assembly 240 is diagonally arranged relative to the mating portion 220 along an extension direction of the second panel surface 211; the second wireless charging module 200 can rotate relative to the first wireless charging module 100 to a misaligned position, and in the misaligned position, a portion of the second housing 210 facing the second wireless charging assembly 240 is exposed from the first housing 110.

In the embodiments, it can be understood that since the first panel surface 111 is arranged with the rotating portion 113, the first wireless charging assembly 130 is disposed on a side of the first housing 110 away from the first panel surface 111. On one hand, this may maximize the size of the transmitter coil of the first wireless charging assembly 130, and on the other hand, the surface of the first housing 110 away from the first panel surface 111 may be fully utilized for placing the electronic devices, enabling the first wireless charging module 100 to wirelessly charge larger electronic devices (e.g., smartphones, tablets, etc.). The second wireless charging assembly 240 is disposed on a side of the second housing 210 near the second panel surface 211, that is, the first wireless charging assembly 130 and the second wireless charging assembly 240 are both disposed on sides of the first wireless charging module 100 and the second wireless charging module 200 facing toward the same direction. In this way, the first wireless charging module 100 and the second wireless charging module 200 of the wireless charging stand can charge two different electronic devices on the same side, thereby making it more convenient for users.

The second wireless charging assembly 240 and the mating portion 220 are arranged diagonally along the extension direction of the second panel surface 211. In this way, during use of the wireless charging stand, an end of the first wireless charging module 100 where the rotating portion 113 is disposed and an end of the second wireless charging module 200 where the mating portion 220 is disposed are located at the bottom, while a portion of the second wireless charging module 200 facing the second wireless charging assembly 240 is located at the top, making it easier for users to place and remove the electronic device corresponding to the second wireless charging module 200. When the user only needs to charge using the first wireless charging module 100, the first wireless charging module 100 can be rotated to overlap with the second wireless charging module 200. In this configuration, the entire wireless charging stand functions as a compact power bank, occupying minimal space and offering greater portability and convenience. When the first wireless charging module 100 and the second wireless charging module 200 are rotated to the misaligned position, both wireless charging modules can be used to charge two electronic devices simultaneously. The proposed design allows users to adjust the relative rotational position of the first wireless charging module 100 and the second wireless charging module 200 according to usage needs, thereby enhancing the product's flexibility.

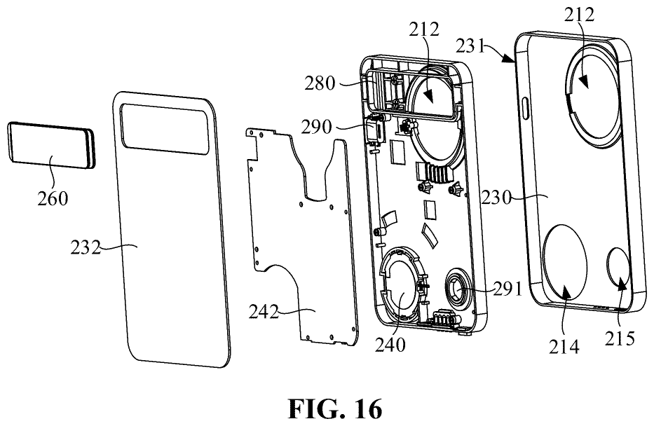

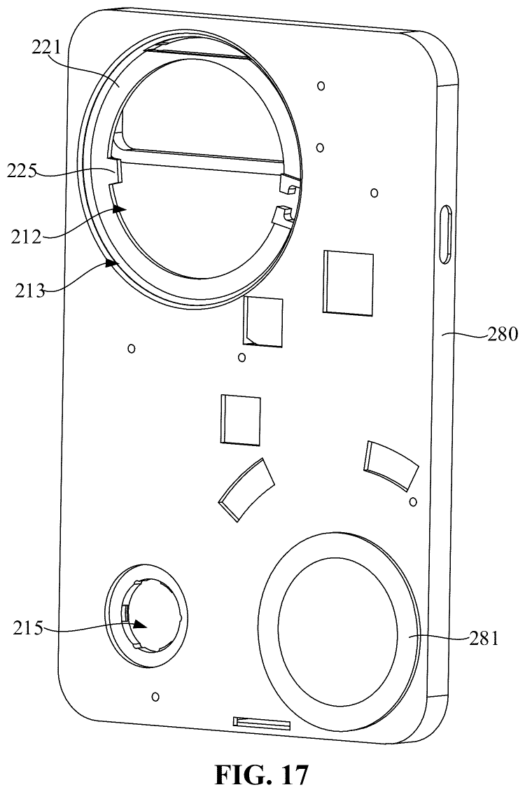

Furthermore, as shown in FIGS. 11, 16, and 18, the first wireless charging assembly 130 includes a first coil 131, and the second wireless charging assembly 240 includes a second coil 241. A diameter of the first coil 131 is greater than a diameter of the second coil 241, ensuring that the wireless output power of the first wireless charging assembly 130 is greater than that of the second wireless charging assembly 240.

In the embodiments, the diameter of the first coil 131 is greater than the diameter of the second coil 241, such that the wireless output power of the first wireless charging assembly 130 is greater than the wireless output power of the second wireless charging assembly 240. In this way, the first wireless charging assembly 130 can charge electronic devices with higher power, such as smartphones, while the second wireless charging assembly 240 can charge electronic devices with lower power, such as Bluetooth earphones or smartwatches, thereby meeting the simultaneous charging needs of different electronic devices. Additionally, since the second wireless charging assembly 240 is disposed near the second panel surface 211, the smaller-diameter second coil 241 is placed inside the second wireless charging module 200 and the larger-diameter first coil 131 is placed inside the first wireless charging module 100. This arrangement optimizes the use of the available area on the first panel surface 111 and the second panel surface 211, resulting in a more rational layout for the entire wireless charging stand.

In some embodiments, referring to FIG. 5, the second wireless charging module 200 can rotate 90 degrees relative to the first wireless charging module 100 toward the misaligned position. When the second wireless charging module 200 rotates 90 degrees relative to the first wireless charging module 100, a first side wall 119 of the first housing 110 aligns with a second side wall 227 of the second housing 210.

In the embodiments, when the second wireless charging module 200 rotates 90 degrees relative to the first wireless charging module 100, the portion of the second housing 210 facing the second wireless charging assembly 240 is exposed from the first housing 110. When the first wireless charging module 100 and the second wireless charging module 200 are rotated 90 degrees relative to each other, the first side wall 119 of the first housing 110 is aligned with the second side wall 227 of the second housing 210, which may ensure that the two wireless charging modules are flush when rotated 90 degrees, preventing users from scraping their hands during use, and maintaining a smooth appearance.

In some embodiments, as shown in FIGS. 5 to 8, the first wireless charging module 100 further includes a first magnetic member 150 disposed adjacent to the first wireless charging assembly 130; the second wireless charging module 200 further includes a support structure 260 and a second magnetic member 250 that is disposed adjacent to the second wireless charging assembly 240; the support structure 260 is connected to a panel surface of the second housing 210 away from the second panel surface 211, and is disposed at a position facing a central portion of the first wireless charging module 100 along an extension direction of the first side wall 119; an end of the support structure 260 away from the second side wall 227 is rotatably connected to the second housing 210, and an end of the support structure 260 near the second side wall 227 can be unfolded to a predetermined angle relative to the second housing 210, to support the first wireless charging module 100 and the second wireless charging module 200 when the second wireless charging module 200 rotates 90 degrees relative to the first wireless charging module 100.

In the embodiments, when the first wireless charging module 100 is designed for charging a mobile phone, the first magnetic member 150 may be arranged around the transmitter coil of the first wireless charging assembly 130 to magnetically attract a magnetic ring inside the mobile phone. When the second wireless charging module 200 is designed for charging an electronic watch or Bluetooth earphones, the second magnetic member 250 is a magnetic block located within the transmitter coil of the second wireless charging assembly 240, designed to magnetically attract a magnetic block inside the electronic watch or Bluetooth earphones.

The structure and form of the support structure 260 may vary widely. For example, the support structure 260 may be designed as a support ring, a support plate, etc. To enhance usability, the support structure 260 is designed to be unfolded to a predetermined angle relative to the second housing 210 and retractable into the second housing 210. The predetermined angle may be designed according to actual requirements, for example, the predetermined angle may specifically be 30 degrees to 50 degrees, such that the first wireless charging module 100 and the second wireless charging module 200 are not too flat or too upright. In some embodiments, the support structure 260 includes a support member 261, a fixed member 262, and a hinge member 263. The fixed member 262 is fixedly connected to the second housing 210, and an end of the support member 261 is rotatably connected to the fixed member 262 via the hinge member 263, enabling the other end of the support member 261 to unfold to a predetermined angle relative to the second housing 210 or be stored within the second housing 210. Therefore, when support is required, the support member 261 can be unfolded to support the entire wireless charging stand, and when support is not required, the support member 261 can be retracted to ensure the flatness of the entire wireless charging stand.

By positioning the support structure 260 such that it faces the first wireless charging module 100 at the midpoint along the extension direction of the first side wall 119, and allowing the end of the support structure 260 near the second side wall 227 to unfold relative to the second housing 210 by a predetermined angle, the support structure 260 can reliably support the midpoint of the first wireless charging module 100, thereby enhancing the overall stability of the wireless charging stand. Additionally, when the support structure 260 is unfolded to support the wireless charging stand, the first side wall 119 of the first wireless charging module 100 and the second side wall 227 of the second wireless charging module 200 are located at the bottom of the entire wireless charging stand and are aligned, thereby improving visual aesthetics and enhancing the product user experience.

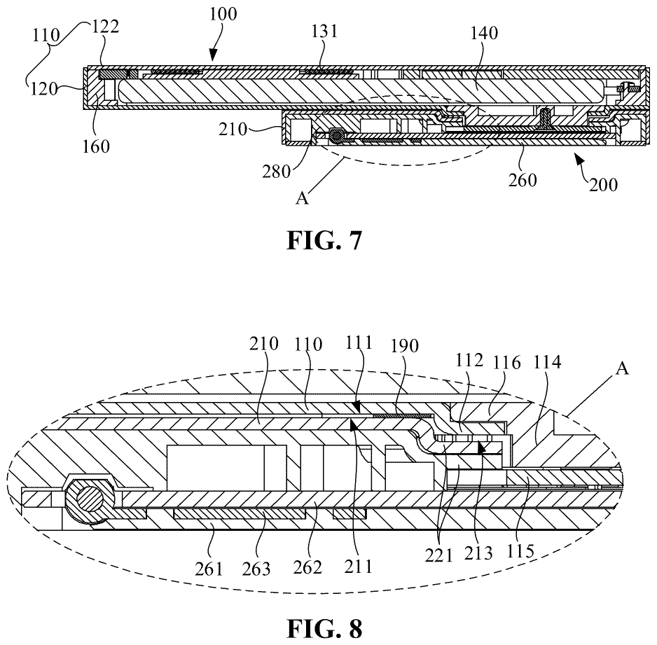

In some embodiments, as shown in FIGS. 7 to 10, the rotating portion 113 is limit-connected to the mating portion 220 in the extension direction of the first axis, preventing the first wireless charging module 100 and the second wireless charging module 200 from separating during rotation. A limiting engagement structure may be arranged on the rotating portion 113 and the mating portion 220, such that the first wireless charging module 100 and the second wireless charging module 200 may be prevented from separating along the extension direction of the rotational axis, thereby effectively preventing the first wireless charging module 100 and the second wireless charging module 200 from separating during rotation, and thus enhancing the overall operational reliability.

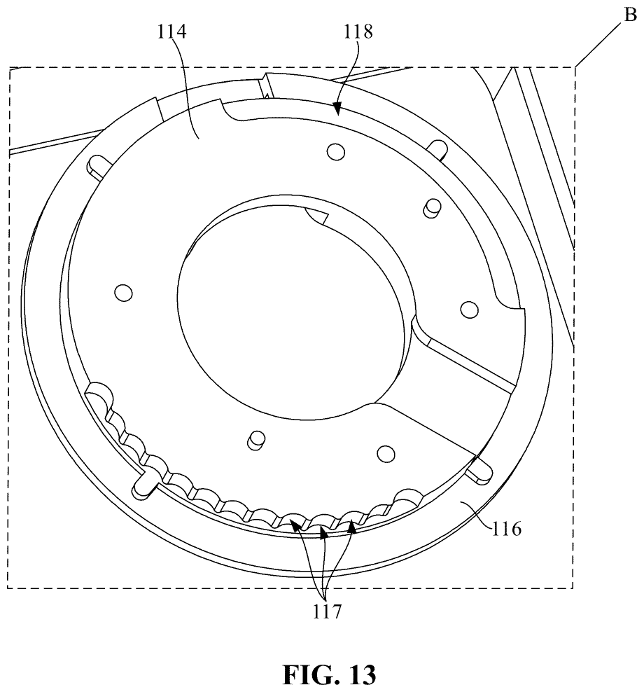

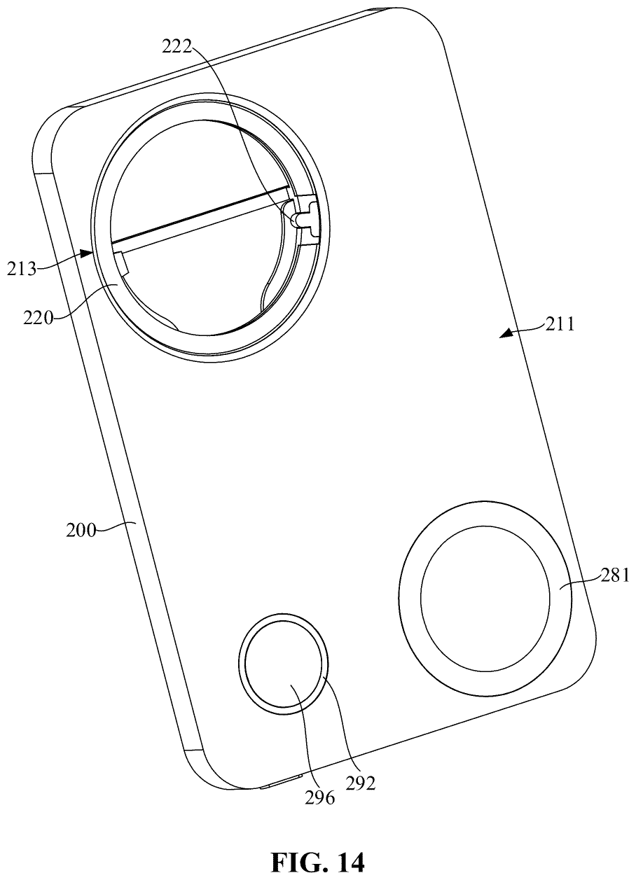

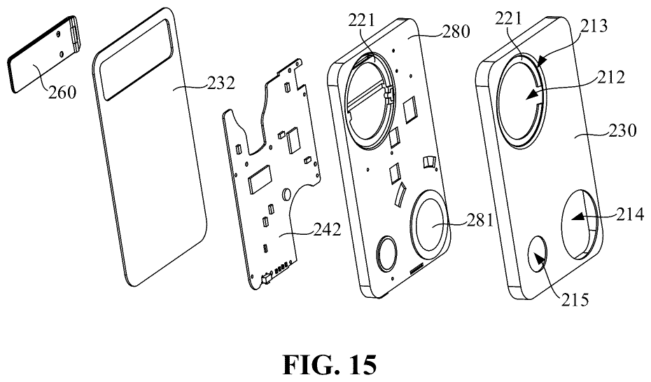

Furthermore, as shown in FIGS. 7 to 10 and 12 to 17, the rotating portion 113 includes a rotating cylinder 114 and a limiting disk 115. The rotating cylinder 114 is fixedly arranged on the first housing 110 and at least partially protrudes from the first panel surface 111. The limiting disk 115 is detachably connected to an end of the rotating cylinder 114 facing the second panel surface 211, and at least a part of an outer peripheral wall of the limiting disk 115 is disposed outside an outer peripheral wall of the rotating cylinder 114; the second panel surface 211 defines a rotating through hole 212 facing the rotating portion 113, and the mating portion 220 includes an embedded protruding ring 221 arranged around an inner peripheral edge of the rotating through hole 212; the embedded protruding ring 221 is adapted to be sleeved on the outer peripheral surface of the rotating cylinder 114, and the embedded protruding ring 221 is arranged, rotatably around the first axis, between the limiting disk 115 and the first panel surface 111.

In the embodiments, the rotating cylinder 114 and the first housing 110 may be integrally formed or may be a disassembled structure. It should be understood that the rotating cylinder 114 is specifically cylindrical in shape, i.e., its cross-section is circular. The limiting disk 115 and the rotating cylinder 114 may be fixedly connected in a detachable manner via screws, clips, or the like, which allows the limiting disk 115 and the rotating cylinder 114 to be removably fixedly connected, facilitating the assembly of the embedded protruding ring 221 between the limiting disk 115 and the first panel surface 111. At least part of the outer peripheral wall of the limiting disk 115 is disposed outside the outer peripheral wall of the rotating cylinder 114, such that the portion of the limiting disk 115 that protrudes from the outer peripheral wall of the rotating cylinder 114 defines a limiting space together with the first panel surface 111. That is, the embedded protruding ring 221 of the mating portion 220 is disposed between the limiting disk 115 and the first panel surface 111, i.e., within the limiting space. The portion of the limiting disk 115 that protrudes from the outer peripheral wall of the rotating cylinder 114 may restrict the movement of the embedded protruding ring 221 along the extension direction of the first axis, thereby effectively preventing the first wireless charging module 100 and the second wireless charging module 200 from separating during rotation. In practice, the limiting disk 115 is arranged inside the second housing 210 to clamp the embedded protruding ring 221 between the first panel surface 111 and the second housing 210. In the embodiments, the rotating through hole 212 is defined on the second panel surface 211, and the rotating cylinder 114 is rotatably arranged within the rotating through hole 212; further, the limiting disk 115 and the first panel surface 111 restrict the embedded protruding ring 221 at the inner peripheral edge of the rotating through hole 212, thereby integrating a rotating structure and an axial limiting structure into the rotating portion 113 and the mating portion 220 simultaneously, which simplifies the rotating and axial limiting structures of the first wireless charging module 100 and the second wireless charging module 200, so as to reduce manufacturing costs.

Furthermore, as shown in FIGS. 7, 8, 12, and 13, the rotating portion 113 further includes an installation disk 116, which is fixedly connected to an end of the rotating cylinder 114 away from the second panel surface 211. An outer peripheral edge of the installation disk 116 protrudes from the outer peripheral wall of the rotating cylinder 114, and the installation disk 116 is axially limited and embedded in an inner wall surface of the first housing 110. The rotating cylinder 114 passes through the first panel surface 111 and is embedded in the rotating through hole 212.

In the embodiments, the installation disk 116 and the rotating cylinder 114 may be integrally formed or separately formed. The installation disk 116 and the first housing 110 may be peripherally limited by structures such as protrusions or grooves. Alternatively, protrusions or grooves may be provided on the outer peripheral wall of the rotating cylinder 114 to engage with grooves or protrusions on the embedded protruding ring 212, thereby enabling the rotating cylinder 114 to rotate peripherally relative to the first housing 110. By providing the installation disk 116, both peripheral and axial limiting of the rotating cylinder 114 relative to the first housing 110 may be achieved, thereby ensuring the reliable fixation of the rotating cylinder 114 to the first housing 110.

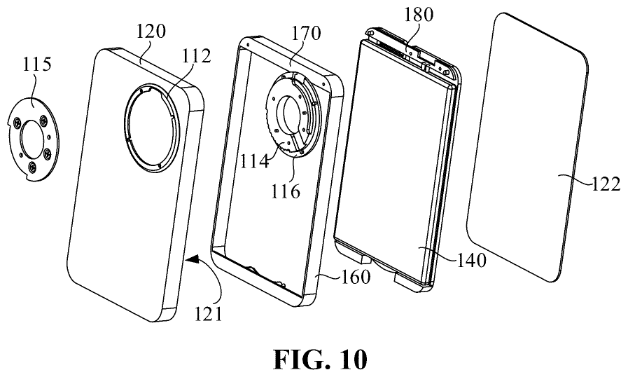

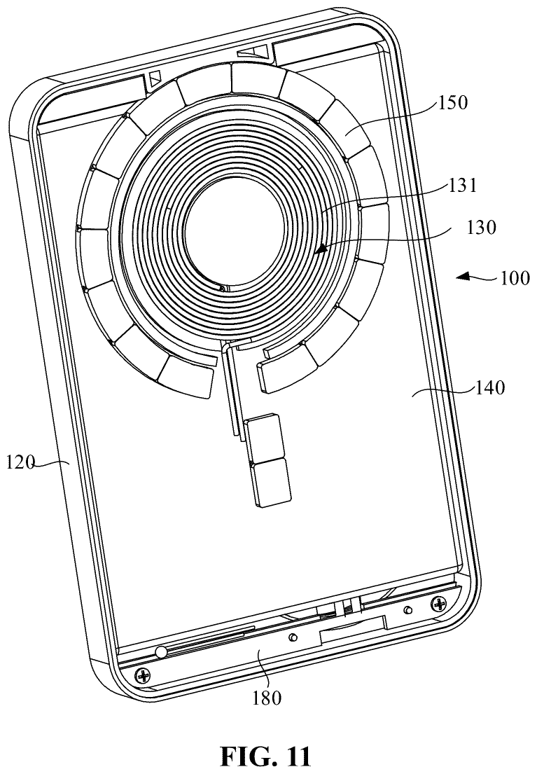

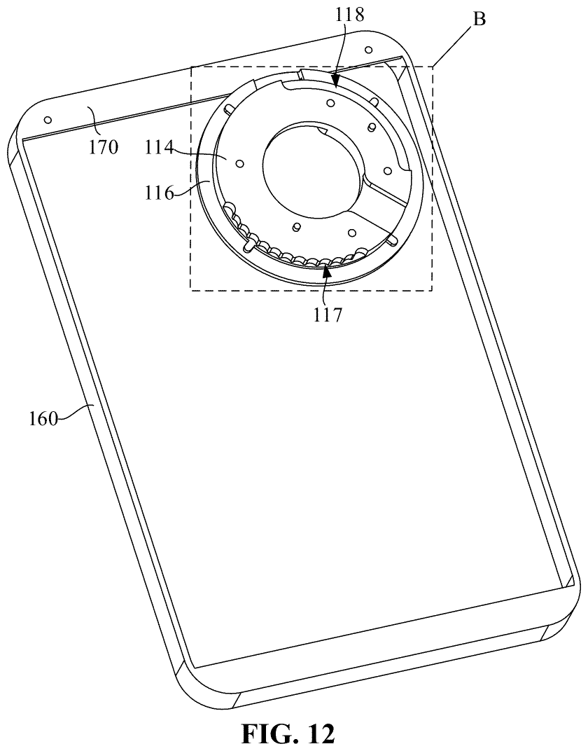

Furthermore, as shown in FIGS. 10 and 12, the first wireless charging module 100 further includes an enclosure frame 160, which is formed integrally with the first housing 110 and surrounds and adheres to an inner peripheral wall of the first housing 110. The enclosure frame 160, the rotating cylinder 114, and the installation disk 116 are integrally formed.

In the embodiments, by arranging the enclosure frame 160 to surround and adhere to the inner peripheral wall of the first housing 110, the structural strength of the peripheral wall of the first housing 110 may be enhanced, thereby improving the structural strength of the entire outer peripheral edge of the first wireless charging module 100. By integrally forming the enclosure frame 160, the rotating cylinder 114, and the installation disk 116, the installation reliability of the rotating cylinder 114 and the installation disk 116 relative to the first housing 110 is ensured while improving the installation convenience of the internal structure, thereby enhancing installation efficiency. In some embodiments, the first housing 110 is made of a metal material, and the enclosure frame 160 is made of an insulating material. For example, the enclosure frame 160 may be made of insulating materials such as plastic or carbon fiber. In this way, the enclosure frame 160 further serves as an insulator, thereby improving the reliability of the product.

Furthermore, as shown in FIGS. 10 to 12, the enclosure frame 160 is connected to the installation disk 116 via a connection plate 170, and the power supply component 140 is arranged inside the enclosure frame 160. The power supply component 140 is electrically connected to the second wireless charging assembly 240 via wires, which pass through a central portion of the rotating cylinder 114 and the rotating through hole 212. The first wireless charging module 100 further includes a wire clamping plate 180, which is pressed against a top of the wires and fixedly connected to the connection plate 170.

In the embodiments, the wires between the power supply component 140 and the second wireless charging assembly 240 pass through the central portion of the rotating cylinder 114 and the rotating through hole 212, thereby preventing the wires from being damaged by winding during relative rotation between the first wireless charging module 100 and the second wireless charging module 200. The wire clamping plate 180 may be fixedly connected to the connection plate 170 via screws. The enclosure frame 160 is connected to the rotating cylinder 114 via the connection plate 170, ensuring the reliability of the connection between the enclosure frame 160 and the installation disk 116. By fixing the wire clamping plate 180 to the connection plate 170, compared to a way where the wire clamping plate 180 is fixed to the first housing 110, damage to the outer surface of the first housing 110 may be avoided, thereby ensuring the integrity and consistency of the outer surface of the first housing 110. By pressing the wire clamping plate 180 against the wires between the power supply component 140 and the second wireless charging assembly 240, the wires may be effectively prevented from lifting and breaking when the first wireless charging module 100 and the second wireless charging module 200 rotate relative to each other.

In some embodiments, referring to FIGS. 7 to 10, 14, and 15, a portion of the first panel surface 111 around the rotating portion 113 protrudes outward to form an annular protrusion 112, and a portion of the second panel surface 211 facing the annular protrusion 112 is recessed inwardly to define an embedding groove 213. The mating portion 220 is disposed within the embedding groove 213. A damping ring 190 is arranged around an outer periphery of the annular protrusion 112, with the damping ring 190 sandwiched between the first panel surface 111 and the second panel surface 211.

Through the engagement of the annular protrusion 112 and the embedding groove 213, the first panel surface 111 and the second panel surface 211 are preliminarily limited in the extension direction of their panel surfaces, preventing the first wireless charging module 100 and the second wireless charging module 200 from deviating from the rotational axis when rotating. By arranging the damping ring 190 around the outer periphery of the annular protrusion 112, the damping ring 190 is sandwiched between the first panel surface 111 and the second panel surface 211, which may prevent the first panel surface 111 and the second panel surface 211 from coming into contact and generating rotational friction noise, and further provide rotational resistance to prevent overly smooth rotation. The damping ring 190 may specifically be made of materials with a high coefficient of friction, such as rubber rings or silicone rings.

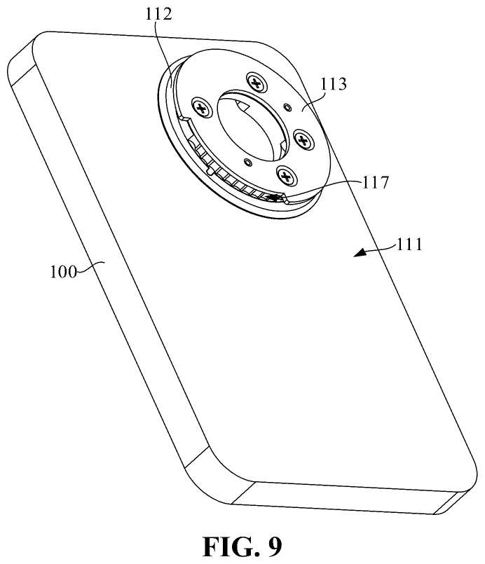

In some embodiments, as shown in FIGS. 9, 12, to 19, an outer peripheral wall of the rotating portion 113 defines multiple positioning slots 117 distributed around the first axis; the mating portion 220 is arranged with a positioning tab 222 corresponding to the positioning slots 117, where an end of the positioning tab 222 is adapted to fit into one of the positioning slots 117, and the end of the positioning tab 222 can be switched to fit into one of adjacent positioning slots 117 during rotation.

In the embodiments, the number of the positioning slots 117 may be selected and designed according to actual requirements and is not specifically limited herein. By providing the positioning slots 117 and positioning tab 222 that can mutually mate on the rotating portion 113 and the mating portion 220, when the first wireless charging module 100 rotates relative to the second wireless charging module 200, the positioning tab 222 and the positioning slots 117 engage to achieve preliminary locking positioning. On one hand, this prevents the first wireless charging module 100 from further rotating relative to the second wireless charging module 200 under the influence of inertial force, thereby facilitating precise adjustment of the rotation angle of the first wireless charging module 100 by the user. On the other hand, when the positioning tab 222 switches between adjacent positioning slots 117 under external force, it emits a mechanical switching sound, enhancing the rotational fun of the first wireless charging module 100 and the second wireless charging module 200, thereby improving user tactile feedback and thus enhancing the overall user experience.

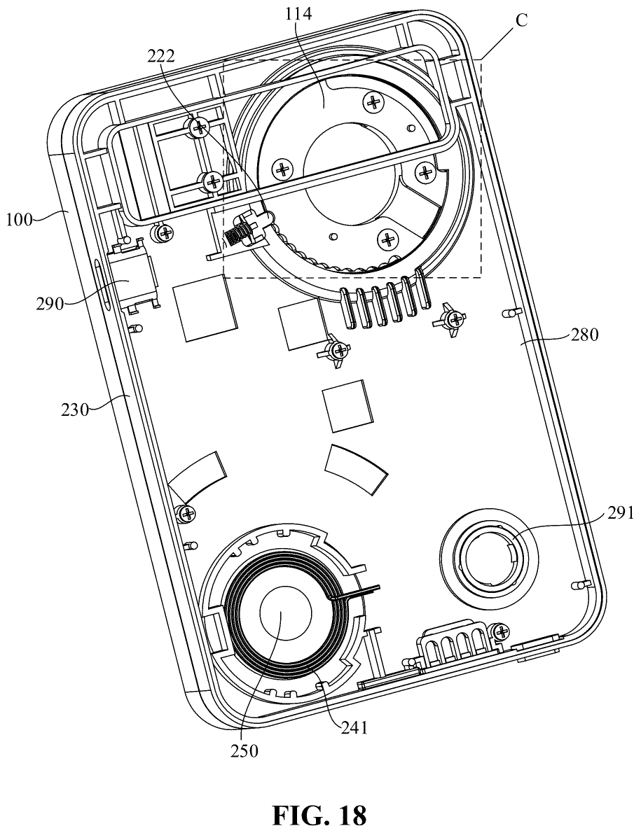

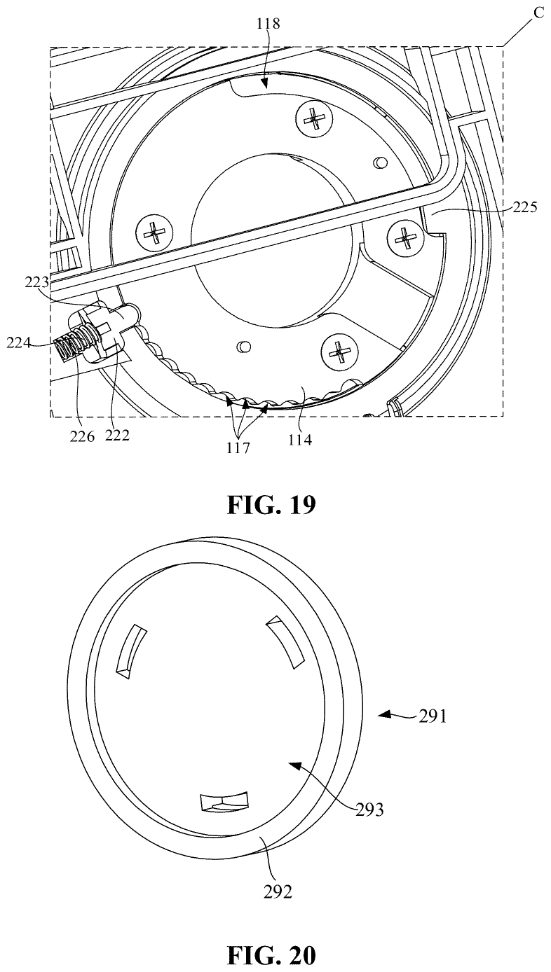

Furthermore, referring to FIGS. 18 and 19, the second wireless charging module 200 further includes a spring 226. The positioning tab 222 includes a protruding portion 223 and a guide post 224 opposite to each other. The protruding portion 223 is adapted to fit into one of the positioning slots 117, and the spring 226 is sleeved on the guide post 224 and sandwiched between the positioning tab 222 and the second housing 210.

The spring 226 may specifically be a compression spring 226. The function of the compression spring 226 is to apply continuous pressure to the positioning tab 222, ensuring that the positioning tab 222 remains tightly in contact with a corresponding positioning slot 117 at any rotation angle, thereby maintaining a stable connection between the modules. When the user adjusts the angle, the spring 226 can be compressed to allow the positioning tab 222 to smoothly switch from one positioning slot 117 to the adjacent positioning slot 117. The spring force of spring 226 automatically returns when the user releases it, pushing the positioning tab 222 back to the nearest positioning slot 117. This ensures that the wireless charging module remains securely locked in a preset position after rotation, thereby enhancing both operational flexibility and module durability.

In some embodiments, as shown in FIGS. 12, 13, and 17 to 19, the outer peripheral wall of the rotating portion 113 further defines a limiting slot 118 extending along its periphery. The mating portion 220 is arranged with a limiting insertion block 225, which is slidable around the first axis and can be inserted into the limiting slot 118, to restrict the rotational angle of the second wireless charging module 200 relative to the first wireless charging module 100.

In the embodiments, the limiting slot 118 may specifically be configured in an arc shape. The extension length of the limiting slot 118 may be designed according to the required rotational angle to be restricted. When the limiting insertion block 225 moves to abut against a side wall of the limiting slot 118 on the periphery of the rotating portion 113, it can stop the rotation of the first wireless charging module 100 and the second wireless charging module 200, thereby reliably controlling the rotational range of the first wireless charging module relative to the second wireless charging module 200.

In some embodiments, as shown in FIGS. 10, 15, and 16, the first housing 110 and the second housing 210 may each be plate-shaped; the first housing 110 includes a first main housing 120 and a first panel 122, the first panel surface 111 is disposed on the first main housing 120, a side of the first main housing 120 away from the first panel surface 111 defines a first opening 121, and the first panel 122 is adapted to cover the first opening 121; the second housing 210 includes a second main housing 230 and a second panel 232, the second panel surface 211 is arranged on the second main housing 230. A side of the second main housing 230 away from the second panel surface 211 defines a second opening 231, and the second panel 232 is configured to cover the second opening 231. The first panel 122 and the second panel 232 may be made of glass material.

The first housing 110 and the second housing 210 may each be plate-shaped, making it easier for users to grip the wireless charging stand. When a user uses the wireless charging stand, his/her hand comes into large-area contact with the first panel 122 and the second panel 232. By using glass material for the first panel 122 and the second panel 232, the tactile comfort and visual aesthetics for users may be significantly enhanced. The first panel 122 may be fixedly connected to the first main housing 120 by adhesive bonding, and the second panel 232 may be fixedly connected to the second main housing 230 by adhesive bonding.

Furthermore, as shown in FIGS. 5, 14 to 17, the first main housing 120 and the second main housing 230 are both made of metal material. The first wireless charging assembly 130 is disposed within the first main housing 120 near the first panel 122.

The second panel 211 defines a through hole 214, and the second wireless charging module 200 further includes an insulated inner housing 280 disposed within the second main housing 230. The insulated inner housing 280 includes a device placement portion 281 adapted to be embedded within the through hole 214, and the second wireless charging assembly 240 is arranged at a position facing the device placement portion 281 of the insulated inner housing 280.

The second wireless charging module 200 can rotate relative to the first wireless charging module 100 to the misaligned position, and in the misaligned position, the device placement portion 281 is exposed from the first housing 110.

In the embodiments, the first main housing 120 and the second main housing 230 are made of metal material, which not only improves the product's tactile feel and appearance quality but also enhances the structural strength of the housing, thereby improving the product's impact resistance. The insulated inner housing 280 is provided inside the second main housing 230 and includes the device placement portion 281 exposed on the second panel surface 211. The second wireless charging assembly 240 is disposed at the position facing the device placement portion 281 on the insulated inner housing 280, thereby preventing the metal main housings from shielding the wireless signals of the second wireless charging assembly 240, thereby ensuring the wireless charging efficiency of the second wireless charging assembly 240.

In some embodiments, the first wireless charging assembly 130 includes a first coil 131, and the second wireless charging assembly 240 includes a second coil 241 and a control board 242. A diameter of the first coil 131 is greater than a diameter of the second coil 241, such that the wireless output power of the first wireless charging assembly 130 is greater than the wireless output power of the second wireless charging assembly 240.

The power supply component 140 is disposed within the first housing 110, and the second wireless charging module 200 further includes a charging interface 290, which is electrically connected to the control board 242. When the charging interface 290 is connected to an external power source, the control board 242 is configured to first supply power to the external device upon detecting a charging signal from the external device placed on the first wireless charging module 100 and the second wireless charging module 200, and then supplies power to the power supply component 140 when it detects that the external device is fully charged or no external device is connected.

In the embodiments, the wireless output power of the first wireless charging assembly 130 is greater than the wireless output power of the second wireless charging assembly 240. In this way, the first wireless charging assembly 130 can charge electronic devices with higher power requirements, such as smartphones, while the second wireless charging assembly 240 can charge electronic devices with lower power requirements, such as Bluetooth earphones or smartwatches, thereby meeting the simultaneous charging needs of different electronic devices.

When the charging interface 290 is connected to an external power source, the built-in power supply component 140 of the wireless charging stand can be charged. When the charging interface 290 is connected to an external device, the built-in power supply component 140 can provide wired power supply to the external device. By arranging the control circuit on the control board 242, when the charging interface 290 is connected to an external power source and the control board 242 detects a charging signal from external devices placed on the first wireless charging module 100 and the second wireless charging module 200, power is first supplied to the external devices. When the control board detects that the external devices are fully charged or no external devices are connected, power is then supplied to the power supply component 140. That is, the wireless charging stand prioritizes charging external devices (such as smartphones, Bluetooth earphones, smartwatches, etc.) when connected to an external power source. Once the external devices are fully charged, the power supply component 140 begins charging itself. This design optimizes the charging sequence, enabling users to quickly charge their desired devices when using the wireless charging stand, which may significantly enhance usability.

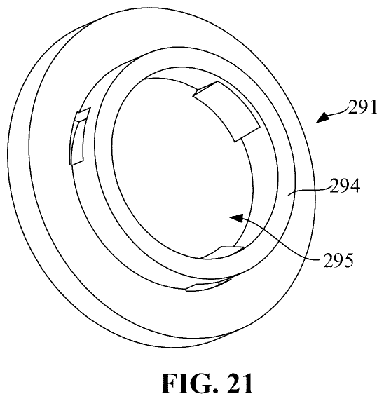

In some embodiments, as shown in FIGS. 5, 14 to 18, 20, and 21, the second panel 211 defines a light-transmitting hole 215 adjacent to the second wireless charging assembly 240. The second wireless charging module 200 further includes a light guide member 291 and a decorative sheet 296. The light guide member 291 includes a light guide ring 292 and a light guide cylinder 294 that are interconnected, with the light guide cylinder 294 arranged within the light-transmitting hole 215, and the light guide cylinder 294 encloses to define a light-emitting diode (LED) accommodation slot 295 with a slot opening inward. The light guide ring 292 is exposed from the light-transmitting hole 215 and encloses to define an installation slot 293, with the decorative sheet 296 arranged within the installation slot 293.

The second wireless charging module 200 can rotate relative to the first wireless charging module 100 to the misaligned position. In the misaligned position, the portion of the second housing 210 facing the second wireless charging assembly 240 and the light guide ring 292 are exposed from the first housing 110.

In the embodiments, the control board 242 is arranged with LED light beads, which are accommodated in the LED accommodation slot 295 to provide a light source for the light guide member 291. The LED light beads can emit light of different colors and adjust the color according to changes in the charging status, thereby intuitively displaying the device's charging status to the user. The light guide member 291 may be made of transparent or semi-transparent light-guiding materials to uniformly transmit light. By arranging the light guide ring 292, when the second wireless charging module 200 is rotated toward the misaligned position, the light guide ring 292 can present a soft and uniform light ring, which can be used to indicate the charging status of external devices, thereby combining functionality with product aesthetics. In practice, an outer surface of the decorative sheet 296 may be flush with the outer surface of the second panel 211. The decorative sheet 296 may be made of the same material as the second panel 211 or of a material with a specific pattern, thereby enhancing the overall aesthetic appeal of the product.

Finally, it should be noted that the above embodiments are only intended to illustrate the technical solutions of the present disclosure, and not to limit them. Although the present disclosure has been described in detail with reference to the foregoing embodiments, those skilled in the art should understand that it is still possible to make modifications to the technical solutions recorded in the foregoing embodiments, or to make equivalent replacements for some of the technical features therein. These modifications or substitutions do not cause the essence of the technical solutions to depart from the spirit and scope of the technical solutions of the embodiments in the present disclosure.

1. A wireless charging stand, comprising a first wireless charging module and a second wireless charging module;
wherein the first wireless charging module comprises a first housing and a first wireless charging assembly arranged within the first housing; the first housing comprises a first panel surface and a rotating portion disposed on the first panel surface;
the second wireless charging module comprises a second housing and a second wireless charging assembly arranged within the second housing; the second housing comprises a second panel surface opposite and adjacent to the first surface, and the second panel surface is arranged with a mating portion; the rotating portion is rotatably connected to the mating portion around a first axis, enabling the second wireless charging module to rotate relative to the first wireless charging module along the first panel surface; the first axis is perpendicular to the first panel surface and the second panel surface;
a power supply component is arranged in the first housing or the second housing and is electrically connected to the first wireless charging assembly and the second wireless charging assembly;
wherein an outer peripheral wall of the rotating portion defines a plurality of positioning slots distributed around the first axis; the mating portion is arranged with a positioning tab corresponding to the plurality of positioning slots, where an end of the positioning tab is adapted to fit into one of the plurality of positioning slots, and the end of the positioning tab is configured to be switched to fit into one of adjacent positioning slots among the plurality of positioning slots during rotation.

2. The wireless charging stand according to claim 1, wherein the first housing and the second housing are each plate-shaped; the first panel surface and the second panel surface have a same shape, and the first panel surface and the second panel surface have a same area; the second wireless charging module is capable of rotating relative to the first wireless charging module to a stacked position, and in the stacked position, an outer peripheral wall of the first housing is aligned with an outer peripheral wall of the second housing.

3. The wireless charging stand according to claim 2, wherein the outer peripheral wall of the first housing extends in a straight line along a thickness of the first housing, and the outer peripheral wall of the second housing extends in a straight line along a thickness of the second housing.

4. The wireless charging stand according to claim 2, wherein the first wireless charging assembly is disposed within the first housing on a side away from the first panel surface, the second wireless charging assembly is disposed within the second housing on a side near the second panel surface, and the second wireless charging assembly is diagonally arranged relative to the mating portion along an extension direction of the second panel surface; the second wireless charging module is capable of rotating relative to the first wireless charging module to a misaligned position, and in the misaligned position, a portion of the second housing facing the second wireless charging assembly is exposed from the first housing.

5. The wireless charging stand according to claim 4, wherein the first wireless charging assembly comprises a first coil, and the second wireless charging assembly comprises a second coil; a diameter of the first coil is greater than a diameter of the second coil, and a wireless output power of the first wireless charging assembly is caused to be greater than a wireless output power of the second wireless charging assembly.

6. The wireless charging stand according to claim 4, wherein the second wireless charging module is capable of rotating 90 degrees relative to the first wireless charging module toward the misaligned position; in a case where the second wireless charging module rotates 90 degrees relative to the first wireless charging module, a first side wall of the first housing is aligned with a second side wall of the second housing.

7. The wireless charging stand according to claim 6, wherein the first wireless charging module further comprises a first magnetic member disposed adjacent to the first wireless charging assembly; the second wireless charging module further comprises a support structure and a second magnetic member that is disposed adjacent to the second wireless charging assembly; the support structure is connected to a panel surface of the second housing away from the second panel surface and is disposed at a position facing a central portion of the first wireless charging module along an extension direction of the first side wall; an end of the support structure away from the second side wall is rotatably connected to the second housing, and another end of the support structure near the second side wall is capable of being unfolded to a predetermined angle relative to the second housing, to support the first wireless charging module and the second wireless charging module in the case where the second wireless charging module rotates 90 degrees relative to the first wireless charging module.

8. The wireless charging stand according to claim 1, wherein the rotating portion is limit-connected to the mating portion in an extension direction of the first axis, for preventing the first wireless charging module and the second wireless charging module from separating during rotation.

9. The wireless charging stand according to claim 8, wherein the rotating portion comprises a rotating cylinder and a limiting disk; the rotating cylinder is fixedly arranged on the first housing and at least partially protrudes from the first panel surface; the limiting disk is detachably connected to an end of the rotating cylinder facing the second panel surface, and at least a part of an outer peripheral wall of the limiting disk is disposed outside an outer peripheral wall of the rotating cylinder; the second panel surface defines a rotating through hole facing the rotating portion, and the mating portion comprises an embedded protruding ring arranged around an inner peripheral edge of the rotating through hole; the embedded protruding ring is adapted to be sleeved on an outer periphery of the rotating cylinder, and the embedded protruding ring is arranged, rotatably around the first axis, between the limiting disk and the first panel surface.

10. The wireless charging stand according to claim 9, wherein the rotating portion further comprises an installation disk fixedly connected to another end of the rotating cylinder away from the second panel surface; an outer peripheral edge of the installation disk protrudes from the outer peripheral wall of the rotating cylinder, and the installation disk is axially limited and embedded in an inner wall surface of the first housing; the rotating cylinder passes through the first panel surface and is embedded in the rotating through hole.

11. The wireless charging stand according to claim 10, wherein the first wireless charging module further comprises an enclosure frame, and the enclosure frame surrounds and adheres to an inner peripheral wall of the first housing; the enclosure frame, the rotating cylinder, and the installation disk are in a one-piece structure.

12. The wireless charging stand according to claim 11, wherein the enclosure frame is connected to the installation disk via a connection plate, and the power supply component is arranged inside the enclosure frame; the power supply component is electrically connected to the second wireless charging assembly via wires, and the wires pass through a central portion of the rotating cylinder and the rotating through hole; the first wireless charging module further comprises a wire clamping plate, and the wire clamping plate is pressed against a top of the wires and fixedly connected to the connection plate.

13. The wireless charging stand according to claim 8, wherein a portion of the first panel surface around the rotating portion protrudes outward to form an annular protrusion, and a portion of the second panel surface facing the annular protrusion is recessed inwardly to define an embedding groove; the mating portion is disposed within the embedding groove; a damping ring is arranged around an outer periphery of the annular protrusion, and the damping ring is clamped between the first panel surface and the second panel surface.

14. (canceled)

15. The wireless charging stand according to claim 1, wherein the second wireless charging module further comprises a spring; the positioning tab comprises a protruding portion and a guide post opposite to each other; the protruding portion is adapted to fit into one of the plurality of positioning slots, and the spring is sleeved on the guide post and clamped between the positioning tab and the second housing.

16. The wireless charging stand according to claim 1, wherein an outer peripheral wall of the rotating portion defines a limiting slot extending along a periphery of the rotating portion; the mating portion is arranged with a limiting insertion block, and the limiting insertion block is slidable around the first axis to be inserted into the limiting slot to restrict a rotational angle of the second wireless charging module relative to the first wireless charging module.

17. The wireless charging stand according to claim 1, wherein the first housing and the second housing are each plate-shaped; the first housing comprises a first main housing and a first panel, the first panel surface is disposed on the first main housing, a side of the first main housing away from the first panel surface defines a first opening, and the first panel is adapted to cover the first opening;
the second housing comprises a second main housing and a second panel, and the second panel surface is arranged on the second main housing; a side of the second main housing away from the second panel surface defines a second opening, and the second panel is configured to cover the second opening;
the first panel and the second panel are each made of a glass material.

18. The wireless charging stand according to claim 17, wherein the first main housing and the second main housing are each made of a metal material; the first wireless charging assembly is disposed within the first main housing near the first panel;
the second panel defines a through hole, and the second wireless charging module further comprises an insulated inner housing disposed within the second main housing; the insulated inner housing comprises a device placement portion adapted to be embedded within the through hole, and the second wireless charging assembly is arranged at a position facing the device placement portion of the insulated inner housing;
the second wireless charging module is capable of rotating relative to the first wireless charging module to a misaligned position, and in the misaligned position, the device placement portion is exposed from the first housing.

19. The wireless charging stand according to claim 1, wherein the first wireless charging assembly comprises a first coil, and the second wireless charging assembly comprises a second coil and a control board; a diameter of the first coil is greater than a diameter of the second coil, and a wireless output power of the first wireless charging assembly is caused to be greater than a wireless output power of the second wireless charging assembly;
the power supply component is disposed within the first housing, and the second wireless charging module further comprises a charging interface electrically connected to the control board; in a case where the charging interface is connected to an external power source, the control board is configured to first supply power to an external device placed on at least one of the first wireless charging module and the second wireless charging module in response to detecting a charging signal from the external device, and to supply power to the power supply component in response to detecting that the external device is fully charged or no external device is connected.

20. The wireless charging stand according to claim 1, wherein the second panel defines a light-transmitting hole adjacent to the second wireless charging assembly; the second wireless charging module further comprises a light guide member and a decorative sheet, and the light guide member comprises a light guide ring and a light guide cylinder that are interconnected, with the light guide cylinder being arranged within the light-transmitting hole; the light guide cylinder encloses to define a light-emitting diode (LED) accommodation slot with a slot opening inward; the light guide ring is exposed from the light-transmitting hole and encloses to define an installation slot, with the decorative sheet being arranged within the installation slot;
the second wireless charging module is capable of rotating relative to the first wireless charging module to a misaligned position, and in the misaligned position, a portion of the second housing facing the second wireless charging assembly and the light guide ring are exposed from the first housing.

21. A wireless charging stand, comprising a first wireless charging module and a second wireless charging module;
wherein the first wireless charging module comprises a first housing and a first wireless charging assembly arranged within the first housing; the first housing comprises a first panel surface and a rotating portion disposed on the first panel surface;
the second wireless charging module comprises a second housing and a second wireless charging assembly arranged within the second housing; the second housing comprises a second panel surface opposite and adjacent to the first surface, and the second panel surface is arranged with a mating portion; the rotating portion is rotatably connected to the mating portion around a first axis, enabling the second wireless charging module to rotate relative to the first wireless charging module along the first panel surface; the first axis is perpendicular to the first panel surface and the second panel surface;
a power supply component is arranged in the first housing or the second housing and is electrically connected to the first wireless charging assembly and the second wireless charging assembly;
wherein an outer peripheral wall of the rotating portion defines a limiting slot extending along a periphery of the rotating portion; the mating portion is arranged with a limiting insertion block, and the limiting insertion block is slidable around the first axis to be inserted into the limiting slot to restrict a rotational angle of the second wireless charging module relative to the first wireless charging module.

22. A wireless charging stand, comprising a first wireless charging module and a second wireless charging module;
wherein the first wireless charging module comprises a first housing and a first wireless charging assembly arranged within the first housing; the first housing comprises a first panel surface and a rotating portion disposed on the first panel surface;
the second wireless charging module comprises a second housing and a second wireless charging assembly arranged within the second housing; the second housing comprises a second panel surface opposite and adjacent to the first surface, and the second panel surface is arranged with a mating portion; the rotating portion is rotatably connected to the mating portion around a first axis, enabling the second wireless charging module to rotate relative to the first wireless charging module along the first panel surface; the first axis is perpendicular to the first panel surface and the second panel surface;
a power supply component is arranged in the first housing or the second housing and is electrically connected to the first wireless charging assembly and the second wireless charging assembly;
wherein the second panel defines a light-transmitting hole adjacent to the second wireless charging assembly; the second wireless charging module further comprises a light guide member and a decorative sheet, and the light guide member comprises a light guide ring and a light guide cylinder that are interconnected, with the light guide cylinder being arranged within the light-transmitting hole; the light guide cylinder encloses to define a light-emitting diode (LED) accommodation slot with a slot opening inward; the light guide ring is exposed from the light-transmitting hole and encloses to define an installation slot, with the decorative sheet being arranged within the installation slot;
the second wireless charging module is capable of rotating relative to the first wireless charging module to a misaligned position, and in the misaligned position, a portion of the second housing facing the second wireless charging assembly and the light guide ring are exposed from the first housing.
